(19) United States
(12) Patent Application Publication
(10) Pub. No.: US 2002/0002772 A1
(43) Pub. Date: Jan. 10, 2002

(54) Method for manufacturing a storage battery terminal

(76) Inventors: Tatsuya Hirano, Osaka (JP); Takuji Nagano, Osaka (JP)

Correspondence Address: FASSE PATENT ATTORNEYS, P.A., P.O. BOX 726, HAMPDEN, ME, 04444-0726, US

(21) Appl. No.: 09/909,150

(22) Filed: Jul. 19, 2001

Related U.S. Application Data
(63) Continuation-in-part of application No. 09/334,395, filed on Jun. 16, 1999, now abandoned.
Application No. 09/334,395 is a division of application No. 08/956,899, filed on Oct. 23, 1997, now abandoned.

(30) Foreign Application Priority Data
Dec. 25, 1996 (JP) 8-345256 (P)

(51) Int. Cl. H05K 3/30

(52) U.S. Cl. 29/883; 29/874; 29/834

(57) ABSTRACT

A lead billet having a large outer diameter cylindrical section and a small outer diameter cylindrical section is positioned in a cavity formed of fixed and movable mold sections. Forcing a punch into the lead billet forms a hollow molding with one end closed. Both ends of the molding are then cut away. The use of a billet with two different outer diameters facilities the plastic flow of the billet material to form a collar with projections for preventing rotation of the terminal mounted with its foot in a cover of a storage battery. Uninterrupted ring ridges below the collar assure a positive seal.

### CROSS-REFERENCE TO RELATED APPLICATIONS

The present Application is a Continuation-In-Part Application of copending application Ser. No. 09/334,395, filed on Jun. 16, 1999. Said copending Application was a Divisional Application of then copending Application U.S. Ser. No. 08/956,899, filed Oct. 23, 1997, now abandoned.

### PRIORITY CLAIM

This application is based on and claims the priority under 35 U.S.C. §119 of Japanese Patent Application 8-345256, filed on Dec. 25, 1996, the entire disclosure of which is incorporated herein by reference. This application also claims the priority under 35 USC 120 of the above identified U.S. patent application Ser. Nos. 08/956,899 and 09/334,395.

### FIELD OF THE INVENTION

The present invention relates to a method for cold forming storage battery terminals in a mold cooperating with a die punch.

### BACKGROUND INFORMATION

Conventional electric storage batteries include a battery jar and a cover closing the upper side of the battery jar. Various elements including a pole plate are enclosed in the battery jar, and two terminals are mounted on or in the cover. Such terminals have been formed by casting.

Cast battery terminals have a number of fine irregularities in their surface. Such irregularities make it hard to achieve a proper seal between the terminal foot and the battery cover even if the terminal is secured to the cover by an insert molding operation while the cover is formed. The above mentioned fine irregularities in the surface of the terminal often causes a fine gap between the terminal and the cover which prevents the formation of a satisfactory seal. As a result, electrolyte contained in the battery jar may disadvantageously leak out through the fine gap by capillary action.

Furthermore, as shown in FIGS. 12 and 13, conventional terminals 1 are provided with a flange 2, annular sealing rings 3 and ribs 13 which innterconnect portions of a plurality of the annular rings 3 formed in the foot of the terminals 1. The terminal foot is molded into the cover and the ribs 13 are intended to prevent rotation of the terminal relative to the cover when the terminal is mounted on or rather partly in the cover. The rings 3 are intended to improve the seal. However, terminal 1 is commonly formed by casting using a split mold 14 shown in FIG. 13. The mold 14 is axially divided into two portions 14A and 14B.

Therefore, the above mentioned ribs 13 must be so shaped that a reverse gradient or so-called back taper relative to the opening and closing directions of each split mold section 14A and 14B is avoided. This requirement limits the position and shape of the ribs 13 around the terminal foot. As a result, the number of ribs 13 is also limited, whereby a cast battery terminal leaves room for improvement with regard to preventing rotation of the terminal 1 when it is mounted on the cover. Moreover, rotation of the terminal 1 in the cover 10 disadvantageously increases the above mentioned gap and facilitates the above-mentioned leakage of electrolyte.

FIGS. 14 and 15 are sectional views through a mounted terminal 1 along the lines XIV-XIV and XV-XV in FIGS. 13, respectively. The sections extend partly through a cover 10. As shown in FIGS. 14 and 15, leakage of electrolyte is prevented by providing a plurality of the annular rings 3 in the mounting foot of the terminal 1. The rings 3 are spaced by grooves in order to make the interface surface between the terminal 1 and the cover 10 larger. No leakage problems arise along the interface portion outside the ribs 13.

However, electrolyte leakage still occurs along the ribs 13 because the above-mentioned grooves are eliminated or made shallower by the ribs. Such leakage of electrolyte may cause an electrical short-circuit between the battery terminals, whereby the lifetime of the battery is reduced. Such leakage also can cause significant damage to equipment next to the battery by corrosion. Therefore, leakage of electrolyte must be positively prevented.

It is known to cold mold battery terminals for example from U.S. Pat. Nos. 5,296,317 (Ratte et al.), or 4,776,197 (Scott), or 5,655,400 (Spiegelberg et al.). Each of these disclosures uses a cylindrical billet or slug produced in a separate prefabrication, for example by extrusion. Since the finished battery terminals have a frusto-conical configuration with a ringed foot, the use of cylindrical slugs or billets is not efficient because movement of substantial slug material volumes in the cold forming die is required particularly for forming the various terminal foot configurations. To facilitate such slug or billet material movement in the cold forming die, substantial preworking steps must be performed on the slug or billet. Ratte et al., for example, suggest several preworking steps including forming a central dead end hole in the billet prior to final shaping of the cylindrical terminal. Such preworking steps are costly and should be minimized. Similarly, material movement should be minimized. Spiegelberg et al. provide a relatively shallow cavity in one end of the cylindrical billet or slug. Billets with an axial hole or cavity do not provide more material where it is most needed, namely for the formation of the terminal foot with its rings and collar. Scott teaches cutting off excess material from the cold molded terminal.

### SUMMARY OF THE INVENTION

The present invention aims at solving the aforementioned sealing and manufacturing problems by avoiding the terminal ribs altogether when the terminals are manufactured to thereby effectively prevent leakage of electrolyte while nevertheless preventing rotation of the terminals when the terminals are installed in a battery cover. The invention also aims at enabling the cold formation of the battery terminals in a simplified cold molding die, thereby avoiding the use of complicated conventional dies.

In a method of manufacturing a terminal for a storage battery according to the present invention, first a billet is cast that has a first large outer diameter billet section having a large diameter end face and a second small outer diameter billet section having a small diameter end face. Both sections are cylindrical and preferably made of lead. The cast billet is then placed with its large diameter end face on a die punch so that the second billet section with its small outer diameter end face faces a first mold cavity portion formed in a first mold section. The first mold cavity portion is then closed by a second mold section having a second mold cavity portion with grooves in said second mold cavity portion. The second mold cavity portion cooperates with the first mold cavity portion to form a closed mold cavity. When the mold cavity is closed, the die punch is forced to move through the closed mold cavity, whereby the small outer diameter billet section is first moved into the first mold cavity portion and then the die punch is moved into the large outer diameter billet section for first displacing material of said small outer diameter billet section into said first mold cavity portion to fill said first mold cavity portion. Forcing the die punch then continues, whereby material of said large outer diameter billet section plastically flows to fill said second mold cavity portion including said grooves in said second mold cavity portion, whereby billet material flows downwardly and radially outwardly, to form said storage battery terminal with an open large terminal diameter end surrounded by terminal ring ridges formed in said grooves and with a closed small diameter terminal end. The mold cavity is then opened and the storage battery terminal is removed.

By starting with a billet that has a large outer diameter cylindrical end and a smaller outer diameter cylindrical end relative to the larger diameter end according to the present invention, the material movement by plastic deformation of the lead billet within the mold cavity is minimized, because the shape of the billet provides more lead material where more material is needed and less lead material where less material is needed. More specifically, more material is needed for the formation of the terminal mounting foot with its rings and collar than is needed for the formation of the tapering end forming a hollow frusto-conical tube portion of the battery terminal.

Another advantage of the invention is seen in that the outer surface of the terminal thus formed by a minimal plastic deformation of the lead billet is much smoother compared with terminals formed by casting. The smooth outer surface of the terminal effectively prevents the formation of a fine gap between the terminal and the battery cover, whereby leakage of electrolyte, that otherwise could result from such a gap, is prevented.

It is noted that the fixed or stationary mold section preferably has a ring recess which becomes part of the closed mold cavity at the entrance end of the fixed mold section. This ring recess is so positioned that material from the large outer diameter billet section is caused to flow into the ring recess to form a collar with protrusions and recesses alternately spaced around the collar. These protrusions will prevent rotation of the terminal in the battery cover, as will be described in more detail below. However, this ring recess could alternatively be positioned in the moveable mold section.

The terminal for a storage battery produced according to the invention is mounted with its terminal foot in the cover of the storage battery. Above the mounting foot with its rings and collar the present terminal has the above mentioned frustoconical hollow tube portion. The collar of the mounting foot of the present battery terminal has radially extending protrusions circumferentially spaced by recesses for preventing rotation of the terminal in the battery cover. Preferably, the transitions between the recesses and the protrusions of the terminal collar are curved so that resin can readily be introduced near the protrusions when the terminal foot is insert molded into the battery cover. As a result, formation of a gap between the terminal and the cover is prevented whereby leakage of electrolyte is also effectively prevented.

### BRIEF DESCRIPTION OF THE DRAWINGS

In order that the invention may be clearly understood, it will now be described in connection with example embodiments, with reference to the accompanying drawings, wherein:

FIG. 1 is a perspective view showing a terminal for a storage battery produced in accordance with an embodiment of the present invention;

FIG. 2 is a plan view of the terminal in the direction of the arrow II shown in FIG. 1;

FIGS. 3 and 4 are cross-sectional views of the molding die used according to the invention and showing the first and second molding steps in the present cold molding process for manufacturing the terminal shown in FIGS. 1 and 2;

FIG. 5A is a cross-sectional view similar to FIGS. 3 and 4, but showing the third molding step in a process of manufacturing the terminal shown in FIGS. 1 and 2;

FIG. 5B is a view showing an enlargement of a region R in FIG. 5A to illustrate the plastic material flow;

FIGS. 6 to 8 are cross-sectional views showing further steps in the present process of manufacturing the terminal shown in FIGS. 1 and 2;

FIG. 9 is a cross-sectional view showing an example of the mounting of the terminal foot of the terminal according to the present invention in a battery cover;

FIG. 10 is a cross-sectional view showing another mounting example of the terminal foot in the battery cover;

FIG. 11 is a perspective view showing a billet such as a lead billet having a large outer diameter cylindrical section and a small outer diameter cylindrical section as used according to the invention;

FIG. 12 is a side view showing an example of a conventional terminal;

FIG. 13 is a plan view of the conventional terminal shown in FIG. 12, whereby the terminal is still in a mold shown by dashed lines;

FIG. 14 is a sectional view along section line XIV-XIV in FIG. 13; and

FIG. 15 is a sectional view along section line XV-XV in FIG. 13.

### DETAILED DESCRIPTION OF PREFERRED EXAMPLE EMBODIMENTS AND OF THE BEST MODE OF THE INVENTION

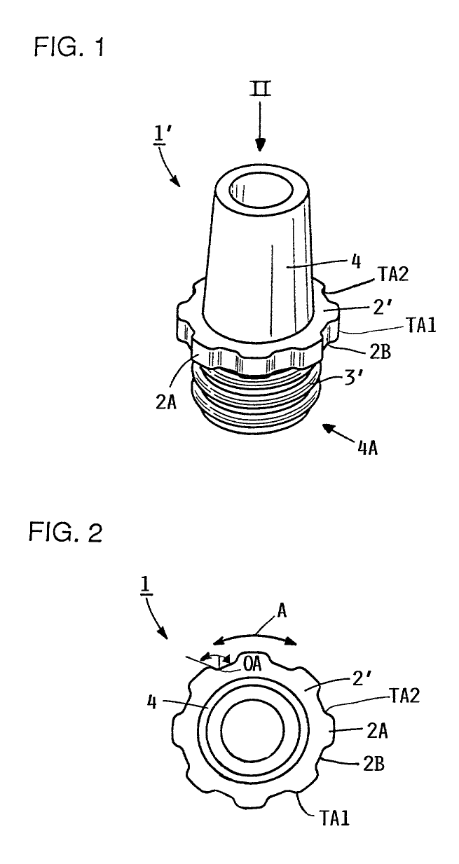

FIG. 1 shows a battery terminal 1′ produced according to the invention. The terminal 1′ includes a slightly frusto-conical tubular portion 4 and a mounting foot 4A. An annular collar 2′ protruding in a radial direction from the tubular portion 4 separates the mounting foot 4A from the tubular portion 4. The collar 2′ is molded to have radially extending protrusions or projections 2A and recesses 2B alternating circumferentially with each other around the collar 2′ to resist rotation of the terminal in the battery cover. The side surface of the mounting foot 4A is molded to have a plurality of ring ridges 3′ that increase the interface surface between the terminal foot 4A and a battery cover 10′ into which the terminal foot 4A is insertion molded as shown in FIGS. 9 and 10.

In FIG. 9 the cover 10′ has a flange 10A covering the collar 2′. In FIG. 10 there is no cover flange. In both instances the terminal foot 4A is fully enclosed in the structure of the cover 10′, except that in FIG. 10 the top surface of the collar 2′ is not covered by the flange 10A. The frusto-conical tubular portion 4 has an end diameter D1 and the mounting foot 4A has a larger diameter D2 thereby providing a large sealing interface.

Referring further to FIGS. 1 and 2, the projections 2A alternating with recesses 2B around the collar 2′ form a radially outer rim of the collar 2′ with teeth which effectively prevent rotation of the terminal 1′ in the direction indicated by an .arrow A in FIG. 2, relative to the battery cover 10′ not shown in FIGS. 1 and 2. As a result, the formation and expansion of a gap between the terminal 1′ and the battery cover 10′ and hence leakage of electrolyte through such a gap is effectively prevented. In addition, the workability in electrically connecting the terminal 1′ to a peripheral apparatus is facilitated by preventing rotation of the terminal 1′ in the battery cover 10′.

As further shown in FIGS. 1 and 2, transition areas TA1 between the circumferential surfaces of the projections 2A and the side walls of the projections 2A are rounded. Similarly, transition areas TA2 between the bottom of the recesses 2B and the side surfaces of the projections are also rounded. These rounded transition areas TA1 and TA2 of the present terminals facilitate the proper filling of the cold molding cavities by billet material, such as lead, during the cold molding operation. The proper mold filling by a plastic deformation of the billet material is further improved by making an angle OA obtuse. The angle OA is defined circumferentially between the bottom of any recess 2B and a side wall of any respective protrusion or projections 2A as shown in FIG. 2.

Further, the shape of the projections 2A is not limited to that shown in FIG. 1 or FIG. 2, but is selectable with due regard to preventing rotation between the terminal and the cover. For example, the projections 2A may be directly formed in the outer surface of the terminal 1′ without providing the collar 2′. The number of projections 2A is also selectable, for example depending on the size of the terminal. Further, though the shape of the collar 2′ is almost circular in the example shown in FIG. 2, the collar may have any shape other than a circle, such as a polygon, e.g. a triangle or square, or an ellipse. In such embodiments, a lower end section of the tubular portion 4 protruding in the radial direction can perform the rotation preventing function of the collar 2′ with its projections 2A.

The method of manufacturing the terminal 1′ shown in FIGS. 1 and 2 will now be described with reference to FIGS. 3 to 8.

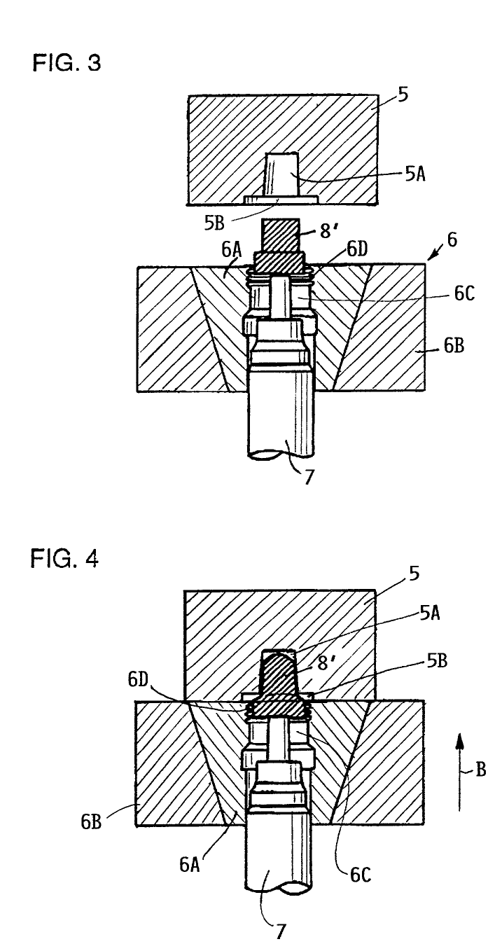

As shown in FIG. 3, a cold molding or shaping tool for manufacturing the terminal 1′, according to the present invention includes a fixed, upper mold section 5, a movable lower mold section 6, and a die punch 7 axially movable through the lower mold section 6 and into the upper mold section 5. The fixed mold section 5 has a mold cavity portion 5A which forms part of a mold cavity or internal space 9 shown in FIG. 4. The cavity portion 5A is open at one end of the fixed mold section 5. The open end is surrounded by a ring space 5B for forming the collar 2′. The movable mold section 6 includes first and second movable mold members 6A and 6B. The mold member 6A is positioned inside mold member 6B. The first and second movable mold members 6A and 6B are movable in the vertical direction, independently of each other for axially separating the mold sections rather than laterally. A cavity portion 6C is provided in the movable mold member 6A. The cavity portion 6C is provided with a plurality of ring spaces 6D for the formation of the ring ridges 3′. The die punch 7 is axially movable through the cavity portion 6C and into the mold cavity portion 5A through the ring space 5B. The cavity portions 5A, 5B, 6C and 6D form the complete mold cavity 9 which will be described below. According to the invention, a lead billet 8′ is used which has a small outer diameter cylindrical section and a large outer diameter cylindrical section as shown in FIG. 11. The lead billet 8′ is positioned with its large diameter end face on the die punch 7 which is movable through mold section 6 as seen in FIGS. 3 to 6.

The lead billet 8′ is preferably formed by casting to provide a double cylindrical shape with two different outer diameters as shown in FIG. 11. When the lead billet 8′ with two different outer diameters is used, the resulting terminal 1′ shown in FIGS. 9 and 10 will have upper and lower portions with significantly different diameters D1 and D2. It is an advantage of the invention that such terminals can readily be formed in accordance with the method of the invention as will be described below. The large diameter D2, relative to the smaller terminal diameter D1, is desirable because a respectively large terminal foot assures a solid, well sealed mounting of the terminal 1′ in the cover 10′ in which the terminal cannot rotate at any time.

Once the billet 8′ has been placed with its large outer diameter end face on the die punch 7 in the lower mold member 6A, as shown in FIG. 3, the mold cavity 9 formed by the cavity portions 5A, 5B, 6C and 6D, is closed as shown in FIG. 4, by moving the second movable mold section 6 with its members 6A and 6B and the die punch 7 upwardly in the direction indicated by an arrow B to abut the movable mold section 6 against the fixed mold section 5, whereby the cavity 9 is closed, and the small diameter end of the lead billet 8′ is thereby inserted into the cavity portion 5A of the fixed mold section 5.

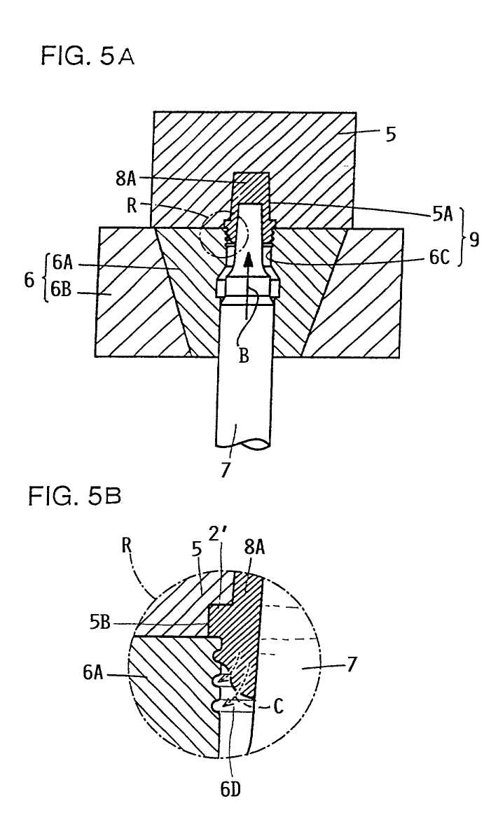

As shown in FIG. 5A, the die punch 7 is further moved upwardly in the direction indicated by the arrow B to force the tip of the punch 7 into the large diameter end of the lead billet 8′, whereby the lead billet 8′ is plastically deformed and a partly hollow molding 8A is formed which has one end namely the upper end closed. The small outer diameter of the billet 8′ is selected by taking into consideration the volume of the final tubular terminal portion 4, the relevant volume portion of the punch 7 and the extent of upward movement of the punch 7. The large outer diameter of the billet 8′ is selected by taking into account the volume of the entire final mounting foot 4A including the collar 2′, the projections 2A, and the ring ridges 3′. In both instances the respective axial lengths of the large and small outer diameter section of the billet 8′ are also taken into account for providing a billet with a volume that completely fills the entire mold cavity 9 by a minimal plastic flow of billet material.

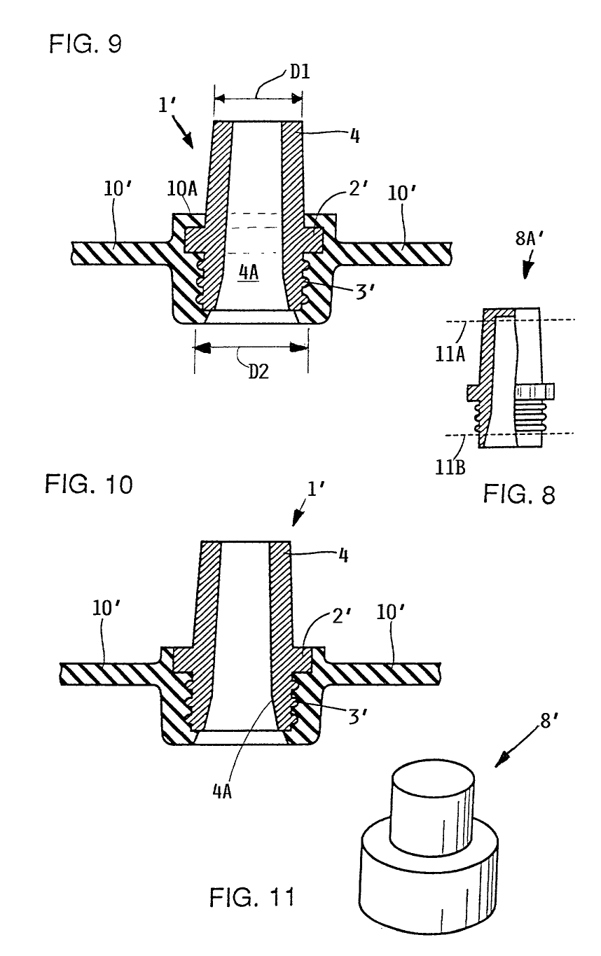

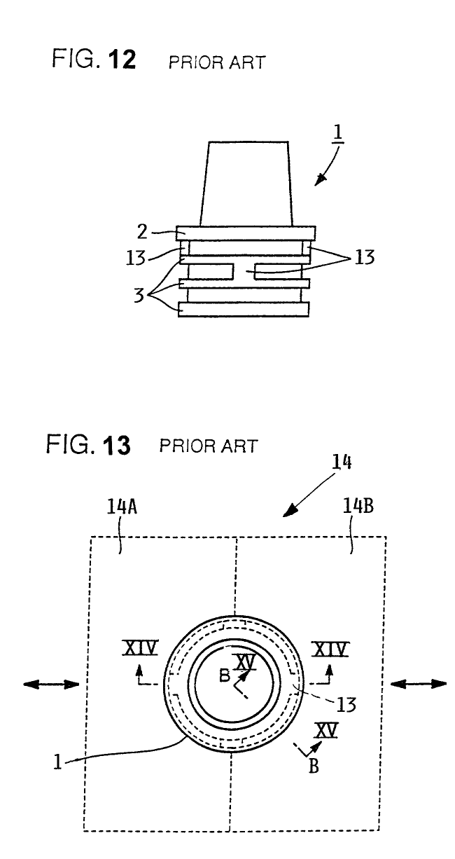

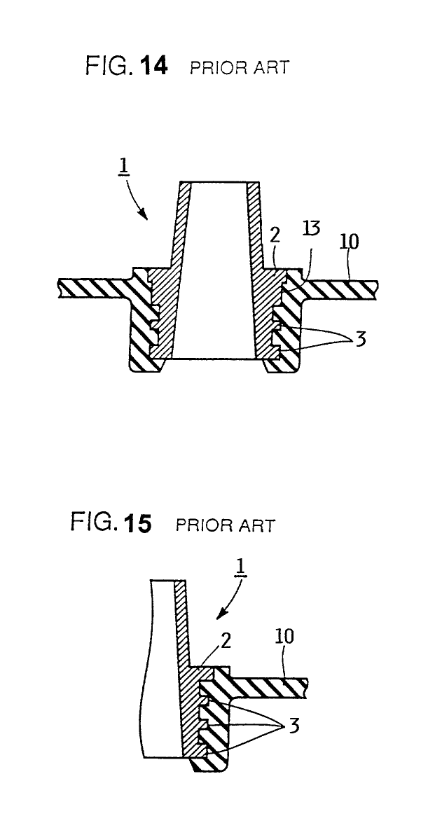

FIG. 5B shows an enlargement of a region R in FIG. 5A. Looking at FIGS. 5A and 5B in conjunction, billet material of the small outer diameter billet section first fills the stationary upper mold cavity portion 5A as the punch 7 moves upwardly. After the cavity portion 5A is filled, the large outer diameter billet section begins to plastically move into the ring recess 5B which in FIG. 5B is already filled to form the collar 2′ and the projections 2A. Then, the material of the large outer diameter billet section further flows by plastic deformation into the ring grooves 6D in the lower cavity portion 6C of the movable mold member 6A to form the ring ridges 3′. The dashed line arrows C in FIG. 5B show the material flow directions for filling the grooves 6D after the ring recess 5B has been filled. The billet material flows downwardly and radially outwardly to fill the ring grooves 6D. Thus, the cavity portion 5A is filled first. Then the ring recess 5B is filled. Then, the grooves 6D are filled to form the molded but not yet finished terminal 8A′ shown in FIGS. 7 and 8.

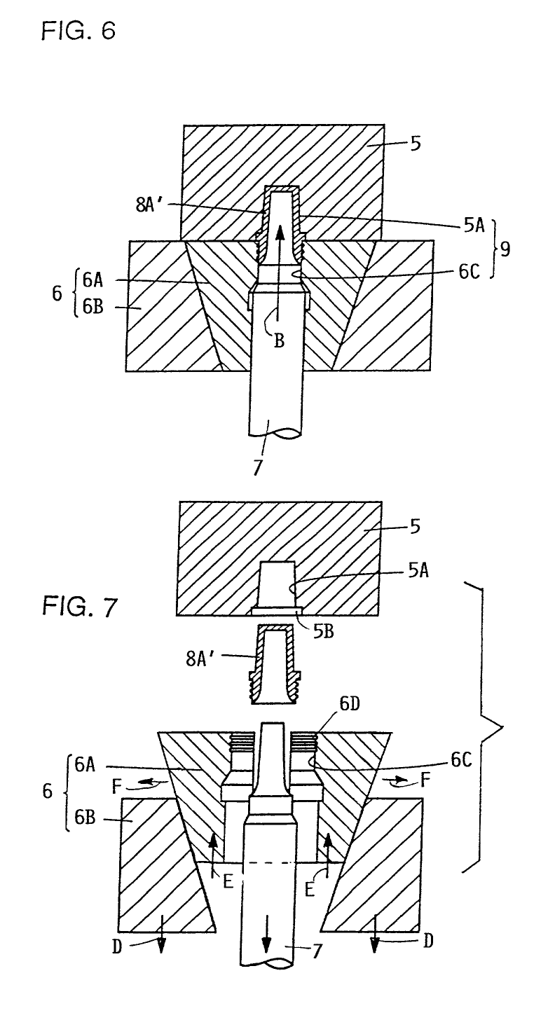

After the entire mold cavity 9 is filled as shown in FIG. 6, the mold is opened as shown in FIG. 7. First, the punch 7 is moved downwardly. Then the movable mold section 6 is moved downwardly as indicated by the arrows D away from the fixed mold section 5 sufficiently for separating the movable mold members 6A and 6B from each other to permit removing the terminal molding 8A′ from the mold. For this purpose the movable mold member 6A is moved upwardly again as indicated by the arrows E. The mold member 6A has at least two mold elements that can be moved away from each other as indicated by the arrows F in FIG. 7. For this purpose, the first movable mold member 6A is axially divided so that its elements can be moved to the right and left as shown by the arrow F in FIG. 7. At this point of the operation the molding 8A′ is still positioned in the cavity portion 5A of the fixed mold 5 as shown in FIG. 6. Molding 8A′ is then removed from the fixed mold as shown in FIG. 7.

FIG. 8 is a cross-sectional view partially showing the molding 8A′ immediately after removal from the fixed mold section 5. Preferably, the upper end and the lower end of the molding 8A′ shown in FIG. 8 are cut away along the dotted lines 11A and 11B. The foregoing steps complete terminal 1′ shown in FIG. 1.

Although the invention has been described with reference to specific example embodiments, it will be appreciated that it is intended to cover all modifications and equivalents within the scope of the appended claims. It should also be understood that the present disclosure includes all possible combinations of any individual features recited in any of the appended claims.

What is claimed is:

1. A method for manufacturing a storage battery terminal, said method comprising the following steps:
a) casting a billet having a first billet section with a large outer diameter and a large end f ace and a second billet section with a small outer diameter and a small end face such that the small outer diameter is smaller than the large outer diameter;
b) placing said large end face on a die punch so that said small end face of said second billet section faces into a first mold cavity portion formed in a first mold section;
c) closing said first mold cavity portion by a second mold section having a second mold cavity portion with grooves in said second mold cavity portion, said second mold cavity portion cooperating with said first mold cavity portion to form a closed mold cavity;
d) forcing said die punch to move through said closed mold cavity into said billet for first displacing said second billet section having said small outer diameter into said first mold cavity portion to fill said first mold cavity portion;
e) continuing to force said die punch into said billet to complete the filling of said first mold cavity portion with billet material from said second small outer diameter billet section and then filing said second mold cavity portion and said grooves in said second mold cavity portion with billet material from said first large outer diameter billet section, whereby billet material flows downwardly and radially outwardly, to form said storage battery terminal with an open large terminal diameter end surrounded by ring ridges (3′) formed in said grooves and with a closed small diameter terminal end; and
f) opening said closed mold cavity and removing said storage battery terminal.

2. The method of claim 1, further comprising providing at least one of said first and second mold cavity portions with a ring recess (5B) having circumferential valleys and ridges, and forcing said first billet section having said large outer diameter to fill said ring recess, thereby forming said storage battery terminal with a collar (2′) having projections (2A) and recesses (2B) between said projections.

3. The method of claim 2, comprising providing said ring recess (5B) in said first mold cavity portion (5A) around an open entrance end of said first mold cavity portion (5A).

4. The method of claim 1, further comprising cutting off at least a portion of a small diameter terminal end of said storage battery terminal.
